(19) United States
(12) Patent Application Publication
(10) Pub. No.: US 2026/0371897 A1
(43) Pub. Date: Nov. 19, 2026

(54) DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jiafan SHI, Beijing (CN); Jianpeng ZHAI, Beijing (CN); Shengxing ZHANG, Beijing (CN); Yang YANG, Beijing (CN); Liqiang CHEN, Beijing (CN); Qian YIN, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/148,032

(22) PCT Filed: Aug. 30, 2024
(86) PCT No.: PCT/CN2024/116129

§ 371 Date: Jul. 15, 2025

(30) Foreign Application Priority Data
Oct. 30, 2023 (CN) 202311424650.4

(51) Int. Cl. H10K 59/80; H10K 59/82; H10K 102/00

(52) U.S. Cl. CPC H10K 59/871; H10K 59/82; H10K 2102/311

(57) ABSTRACT

A display module (100) and a display device (1000). The display module (100) comprises a display panel (10) and a supporting pad (20). The display panel (10) comprises a body portion (11), a binding portion (13), and a bending portion (12) located between the body portion (11) and the binding portion (13). The bending portion (12) is bent along a bending axis extending in a first direction (X) towards a non-display side (11B) of the body portion (11), so that the binding portion (13) is bent to the non-display side (11B) of the body portion (11). The supporting pad (20) is located between the body portion (11) and the binding portion (13); the supporting pad (20) comprises a first sub-portion (21) and a second sub-portion (22); along the first direction (X), the second sub-portion (22) is located on at least one side of the first sub-portion (21); and two ends of the first sub-portion (21) are flush with two ends of the supporting pad (20). The first sub-portion (21) is configured such that there is no adhesive force between the first sub-portion (21) and an adhesion jig when the first sub-portion (21) is separated from the adhesion jig.

### CROSS-REFERENCE TO RELATED APPLICATIONS

This application is a national phase entry under 35 USC 371 of International Patent Application No. PCT/CN2024/116129, filed on Aug. 30, 2024, which claims priority to Chinese Patent Application No. 202311424650.4, filed on Oct. 30, 2023, each are incorporated herein by reference in their entirety.

### TECHNICAL FIELD

The present disclosure relates to the field of display technologies, and in particular, to a display module and a display device.

### BACKGROUND

Organic light-emitting diodes (OLEDs) have been widely used in the display field due to self-luminescence, low driving voltage, high luminous efficiency, fast response speed, flexible display, and other advantages. With the rapid development of display technologies, display technologies such as a liquid crystal display (LCD) device, an organic light-emitting diode (OLED) display device, a quantum dot light-emitting diode (QLED) display device and a mini/micro light-emitting diode (MLED) display device have been widely used in people's daily lives. For example, smart phones, wearable watches, televisions, laptops and car displays have gradually spread in people's lives.

### SUMMARY

In an aspect, a display module is provided. The display module includes a display panel and a support pad. The display panel includes a main body portion, a bonding portion, and a bending portion located between the main body portion and the bonding portion. The main body portion has a display side and a non-display side that are disposed opposite to each other, and the bending portion is bent around a bending axis extending in a first direction towards the non-display side of the main body portion, so that the bonding portion is bent to the non-display side of the main body portion. The support pad is located between the main body portion and the bonding portion. The support pad includes a first sub-portion and a second sub-portion. In the first direction, the second sub-portion is located on at least one side of the first sub-portion, and two ends of the first sub-portion are flush with two ends of the bonding portion. The first sub-portion is configured to have no adhesive force with an adsorption jig when separated from the adsorption jig.

In some embodiments, the support pad includes a first support layer, a support portion and a first adhesive layer. In the first direction, two ends of the first support layer extend beyond the two ends of the bonding portion, and a surface of the first support layer proximate to the bonding portion is provided with a receiving groove therein. An orthographic projection of the receiving groove on the main body portion is located within an orthographic projection of the bonding portion on the main body portion. The support portion is located in the receiving groove; and the first support layer and the bonding portion are connected by the support portion. The first adhesive layer is located on a side of the first support layer away from the bonding portion, and overlapped with and flush with the first support layer.

In some embodiments, the support portion includes a second adhesive layer, and the first support layer and the bonding portion are stuck by the second adhesive layer.

In some embodiments, the support portion includes a second adhesive layer, a second support layer and a third adhesive layer. The second support layer is located on a side of the second adhesive layer away from the bonding portion. The third adhesive layer is located on a side of the second support layer away from the bonding portion.

In some embodiments, the second support layer has a single-layer structure or a multiple-layer structure.

In some embodiments, a material of the first adhesive layer includes pressure sensitive adhesive, and/or a material of the second adhesive layer includes pressure sensitive adhesive, and/or a material of the third adhesive layer includes pressure sensitive adhesive.

In some embodiments, a surface of the support portion proximate to the bonding portion is flush with a surface of the first support layer proximate to the bonding portion.

In some embodiments, a boundary of an orthographic projection of the support portion on the main body portion and an outer boundary of an orthographic projection of the receiving groove on the main body portion have a gap therebetween.

In some embodiments, in the first direction, a distance between a boundary of the orthographic projection of the bonding portion on the main body portion and an outer boundary of an orthographic projection of the receiving groove on the main body portion is in a range of 1.7 mm to 2.9 mm, inclusive.

In some embodiments, in the first direction, a distance between an outer boundary of an orthographic projection of the first support layer on the main body portion and a boundary of an orthographic projection of the bonding portion on the main body portion is in a range of 150 μm to 250 μm, inclusive.

In some embodiments, the support pad includes a first support layer, a fourth adhesive layer and a first adhesive layer. In the first direction, two ends of the first support layer extend beyond the two ends of the bonding portion. The fourth adhesive layer is located on a side of the first support layer proximate to the bonding portion, and overlapped with and flush with the first support layer, and a portion of the fourth adhesive layer extending beyond the bonding portion has no stickiness. The first adhesive layer is located on a side of the first support layer away from the bonding portion, and overlapped with and flush with the first support layer.

In some embodiments, a material of the fourth adhesive layer is a light-curable adhesive layer.

In some embodiments, in the first direction, a distance between an outer boundary of an orthographic projection of the first support layer on the main body portion and a boundary of an orthographic projection of the bonding portion on the main body portion is in a range of 150 μm to 250 μm, inclusive.

In some embodiments, the display module further includes a back film located on the non-display side of the display panel. The back film includes a first back sub-film and a second back sub-film, and the first back sub-film and the second back sub-film are disconnected at the bending portion.

In another aspect, a display device is provided. The display device includes the display module as described in any of the above embodiments.

In some embodiments, the display device further includes a middle frame. The middle frame includes a bottom plate and a side frame disposed around the bottom plate. The bottom plate is disposed on a side of the bonding portion of the display panel away from the main body portion, and the side frame is disposed around a circumference of the display panel.

In some embodiments, the display device further includes a fixing portion connecting the middle frame and the display module, and an orthographic projection of the fixing portion on a plane where the main body portion is located is located outside a display area of the display panel.

In some embodiments, the fixing portion includes a first fixing portion and a second fixing portion. The first fixing portion covers a surface of the bending portion away from the side frame and extends to the main body portion and the bonding portion. The second fixing portion covers a surface of the bending portion proximate to the side frame and extends to the main body portion and the bonding portion.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a structural diagram of a display device in an unfolded state, in accordance to some embodiments;

FIG. 3 is a cross-sectional view taken along a section line A-A in FIG. 1;

FIG. 4 is a structural diagram of a display panel, in accordance with some embodiments;

FIG. 5 is another cross-sectional view taken along a section line A-A in FIG. 1;

FIG. 6 is a structural diagram of a display module, in accordance with some embodiments;

FIG. 7 is a cross-sectional view taken along a section line B-B in FIG. 1;

FIG. 8 is another cross-sectional view taken along a section line B-B in FIG. 1;

FIG. 9 is yet another cross-sectional view taken along a section line B-B in FIG. 1; and

FIG. 10 is a structural diagram of positions of a circuit board and a bonding portion, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

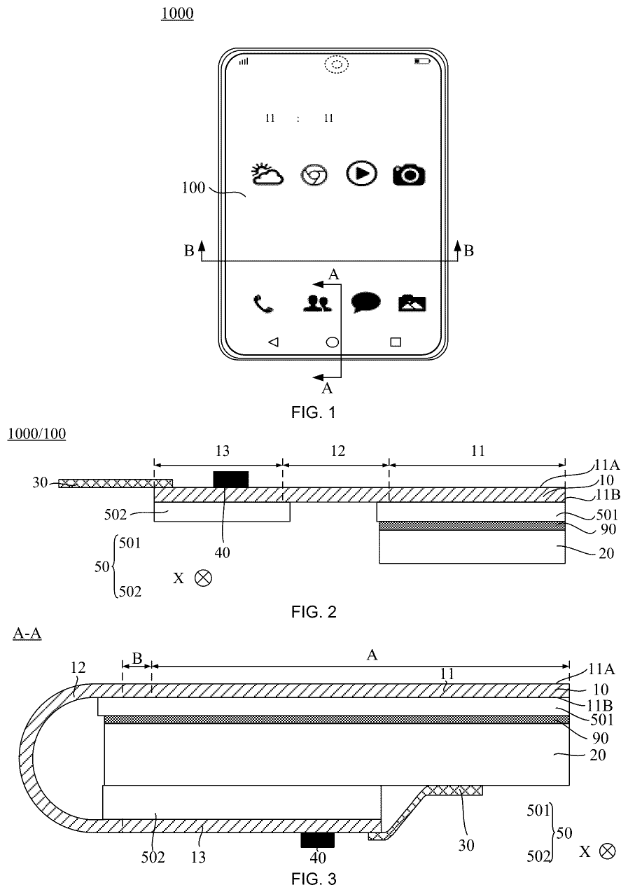

As shown in FIG. 1, some embodiments of the present disclosure provide a display device 1000, and the display device 1000 may be any device that displays images whether in motion (e.g., a video) or stationary (e.g., a static image), and regardless of text or image.

For example, as shown in FIG. 1, the display device 1000 may be any product or component having a display function, such as a television, a laptop, a tablet computer, a mobile phone, a personal digital assistant (PDA), a navigator, a car display, a flight display, a wearable device, or a virtual reality (VR) device.

In some embodiments, as shown in FIGS. 2 and 3, the display device 1000 includes a display module 100. The display module 100 includes a display panel 10 and a support pad 20.

The display panel 10 may be an organic light-emitting diode display panel, a quantum dot light-emitting diode display panel, a mini/micro light-emitting diode display panel, a liquid crystal display panel, a plasma display panel, a field emission display panel, an electrowetting display panel, an electrophoretic display panel, or the like, and the embodiments of the present disclosure do not specifically limit here.

Some embodiments of the present disclosure are exemplarily described below by considering an example where the display panel 10 is an OLED display panel, but the implementations of the present disclosure include are not limited thereto, and any other display panel may also be considered as long as the same technical concept is applied.

In some embodiments, as shown in FIG. 2, the display panel 10 includes a main body portion 11, a bending portion 12 and a bonding portion 13 that are sequentially connected. The bending portion 12 is located on a side of the main body portion 11, and the bonding portion 13 is located on a side of the bending portion 12 away from the main body portion 11. That is, the bending portion 12 is located between the main body portion 11 and the bonding portion 13.

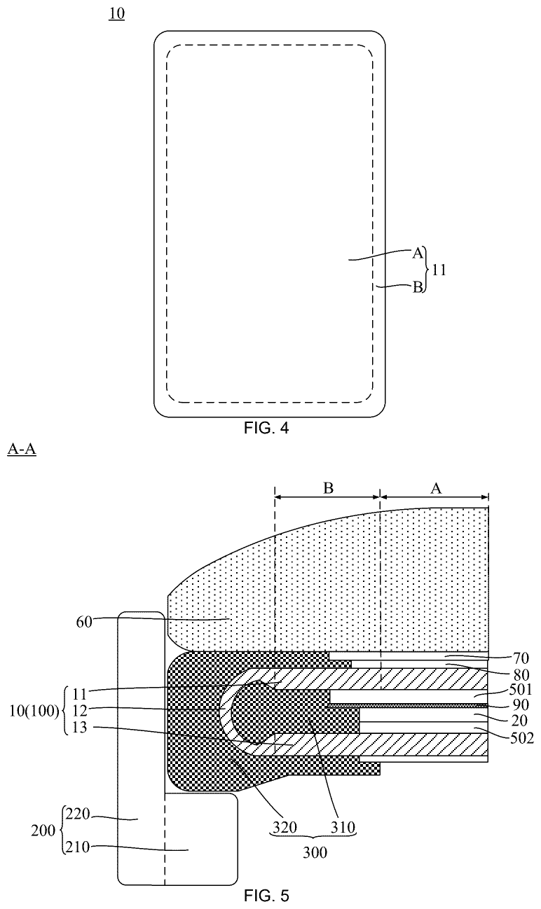

As shown in FIG. 3, the main body portion 11 may be a portion of the display panel 10 for displaying images, that is, the main body portion 11 has a display area A. The main body portion 11 may further include a peripheral area B, and the peripheral area B is provided on at least one side of the display area A. FIG. 4 illustrates an example in which the peripheral region B is disposed around the display region A.

For example, as shown in FIG. 4, the display area A is substantially in a shape of any of a circle, an ellipse, a rectangle, and the like, and the embodiments of the present disclosure do not specifically limit here.

Herein, the description of “substantially in a shape of a circle or an ellipse” refers to a shape of a circle or an ellipse as a whole, but is not limited to a standard circle or a standard ellipse. That is, the “circle or ellipse” here not only includes a shape of a basic circle or ellipse, but also includes a shape similar to a circle or ellipse.

Herein, the description of “substantially in a shape of a rectangle” refers to a shape of a rectangle as a whole, but is not limited to a standard rectangle. That is, the “rectangle” here not only includes a shape of a basic rectangle, but also includes a shape similar to a rectangle. For example, long sides and short sides of the rectangle are curved at each intersecting position (i.e., at each corner), i.e., the corners are smooth and the shape is a rounded rectangle. The following will be described by considering an example in which the display area A is substantially in a shape of a rounded rectangle.

As shown in FIG. 2, the main body portion 11 has a display side 11A and a non-display side 11B that are disposed opposite to each other. It will be noted that the display side 11A refers to a side of the main body portion 11 for displaying an image (an upper side of the main body portion 11 in FIG. 2), and the non-display side 11B refers to the other side opposite to the display side 11A (a lower side of the main body portion 11 in FIG. 2).

As shown in FIG. 2, the bonding portion 13 may be a portion of the display panel 10 for being bonded and connected to the circuit board 30. As shown in FIG. 3, through a bending process, the bending portion 12 may be bent around a bending axis extending in a first direction X towards the non-display side 11B of the main body portion 11 of the display panel 10, so that the bonding portion 13 is bent to the non-display side 11B of the main body portion 11, thereby reducing a frame of the display device 1000. The bending axis is not an actual structure existing in the display panel 10, but is only a concept proposed to illustrate a process of bending the display panel 10.

As shown in FIG. 3, after the bonding portion 13 is bent, the circuit board 30 may be bent along with the display panel 10 to the non-display side 11B of the main body portion 11, so as to achieve a purpose of reducing the frame of the display device 1000. A portion of the circuit board 30 is located on a side of the main body portion 11 proximate to the bonding portion 13 and stuck to the main body portion 11, and another portion of the circuit board 30 is located on a side of the bonding portion 13 away from the main body portion 11 and bonded to the bonding portion 13. It can be understood that the description of a component being stuck to another component may mean that the two components are in direct contact and stuck together, or mean that there is another structure between the two components, and the component or the another component is stuck to the structure.

It will be noted that a bending radius of the bending portion 12 may be in a range of 0.1 mm to 0.5 mm, inclusive. For example, the bending radius of the bending portion 12 is any of 0.1 mm, 0.2 mm, 0.3 mm, 0.35 mm, 0.4 mm and 0.5 mm.

It will be understood that the smaller the bending radius of the bending portion 12 is, the narrower the frame of the display device 1000 corresponding to the bending portion 12 can be designed to be, which is conducive to a narrow frame design of the display device 1000. For example, the bending radius of the bending portion 12 may be in a range of 0.1 mm to 0.2 mm, inclusive. For example, the bending radius of the bending portion 12 is any of 0.12 mm, 0.15 mm and 0.18 mm, so that the frame of the display device 1000 corresponding to the bending portion 12 may be made rather narrow.

As shown in FIG. 3, the support pad 20 is located between the main body portion 11 and the bonding portion 13, and the main body portion 11 and the bonding portion 13 are stuck by the support pad 20.

Based on the above structure, a process of the bending process may be described as follows. In the first step, a support pad 20 is provided on the non-display side 11B of the main body portion 11. In the second step, an adsorption jig is used to be in contact with a surface of the bonding portion 13 proximate to the circuit board 30 to adsorb the bonding portion 13. In the third step, the bonding portion 13 is bent towards the non-display side 11B of the main body portion 11 of the display panel 10, so that the bonding portion 13 is located on a side of the support pad 20 away from the main body portion 11, and there is a gap between the bonding portion 13 and the support pad 20. In the fourth step, the adsorption jig moves the bonding portion 13 towards the main body portion 11, so that the bonding portion 13 and the support pad 20 are stuck. In the fifth step 5, the adsorption jig is removed.

As shown in FIG. 5, the display device 1000 further includes a middle frame 200. The middle frame 200 includes a bottom plate 210 and a side frame 220 disposed around the bottom plate 210. The bottom plate 210 is disposed on a side of the bonding portion 13 of the display panel 10 away from the main body portion 11, and an orthographic projection of the bottom plate 210 on a plane where the main body portion 11 is located is located outside the display area A. The side frame 220 is disposed around a circumference of the display panel 10. The middle frame 200 and the display module 100 may be connected by an edge injection molding (also referred to as insert molding) technology. That is, a fixing portion 300 is formed by the edge injection molding technology, the fixing portion 300 connects the middle frame 200 and the display module 100, and an orthographic projection of the fixing portion 300 on the plane where the main body portion 11 is located is located outside the display area A. With such a provision, the frame of the display device 1000 may be reduced.

For example, as shown in FIG. 5, the fixing portion 300 includes a first fixing portion 310 and a second fixing portion 320. The first fixing portion 310 covers a surface of the bending portion 12 away from the side frame 220, and extends to the main body portion 11 and the bonding portion 13. The second fixing portion 320 covers a surface of the bending portion 12 proximate to the side frame 220, and extends to the main body portion 11 and the bonding portion 13.

In some related arts, in the first direction, two ends of the support pad extend beyond two ends of the bonding portion. During the bending process, the adsorption jig may adhere to the support pad. When the adsorption jig is removed from the bonding portion, the adsorption jig will drive a main body of the support pad to detach. In some other related arts, in the first direction, two ends of the support pad are retracted relative to two ends of the bonding portion, so that a region of the support pad that is retracted relative to the bonding portion, a portion of the bonding portion extending beyond the support pad, and an injection mold form a first overflow adhesive channel. During the edge injection molding, the injected adhesive flows through the first overflow adhesive channel to other parts (e.g., the display area) of the display module, thereby causing abnormal display of the display module.

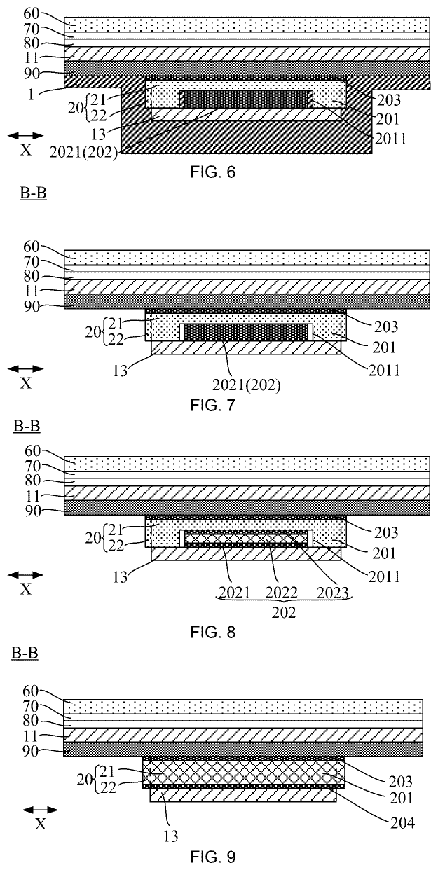

In order to solve the above problems, as shown in FIGS. 6 to 10, a support pad 20 provided in some embodiments of the present disclosure includes a first sub-portion 21 and a second sub-portion 22. In the first direction X, the second sub-portion 22 is located on at least one side of the first sub-portion 21, and two ends of the first sub-portion 21 are flush with two ends of the bonding portion 13. That is, in the first direction X, an end of the support pad 20 extends beyond the bonding portion 13 and the other end of the support pad 20 is flush with the bonding portion 13; alternatively, both ends of the support pad 20 extend beyond both ends of the bonding portion 13.

As shown in FIG. 6, during the edge injection molding, a portion (i.e., the second sub-portion 22) of the support pad 20 extending beyond the bonding portion 13 is in contact with an injection mold 1, so that the first overflow adhesive channel in the related arts may be prevented from being formed, thereby preventing the injected adhesive from flowing through the first overflow adhesive channel to other parts of the display module 100. As a result, a display effect of the display module 100 may be improved.

The first sub-portion 21 is configured to have no adhesive force with the adsorption jig when separated from the adsorption jig. Such a provision may improve the problem that the support pad 20 is detached from the main body portion 11 caused by adhesion between the adsorption jig and the first sub-portion 21.

The specific structure of the support pad 20 will be illustrated by examples below.

In some embodiments, as shown in FIGS. 7 and 8, the support pad 20 includes a first support layer 201, a support portion 202 and a first adhesive layer 203. In the first direction X, two ends of the first support layer 201 extend beyond two ends of the bonding portion 13. A receiving groove 2011 is provided in a surface of the first support layer 201 proximate to the bonding portion 13. An orthographic projection of the receiving groove 2011 on the main body portion 11 is located within an orthographic projection of the bonding portion 13 on the main body portion 11. The support portion 202 is located in the receiving groove 2011, and the first support layer 201 and the bonding portion 13 are connected by the support portion 202. The first adhesive layer 203 is located on a side of the first support layer 201 away from the bonding portion 13, and is overlapped with and flush with the first support layer 201.

That is to say, in the first direction X, a portion of the first support layer 201 not extending beyond the bonding portion 13, the support portion 202, and a portion of the first adhesive layer 203 not extending beyond the bonding portion 13 form the first sub-portion 21; and a portion of the first support layer 201 extending beyond the bonding portion 13 and a portion of the first adhesive layer 203 extending beyond the bonding portion 13 form the second sub-portion 22. In addition, in the first direction X, the second sub-portion 22 is located on both sides of the first sub-portion 21.

With such a provision, the second sub-portion 22 is located on both sides of the first sub-portion 21, so that the first overflow adhesive channel in the related arts may be prevented from being formed, thereby improving the problem of affecting the normal display of the display module 100 caused by the injected adhesive flowing to other parts of the display module 100. In addition, during bending, the portion of the first support layer 201 extending beyond the bonding portion 13 is in direct contact with the adsorption jig, that is to say, there is no adhesive layer between the first support layer 201 and the adsorption jig, i.e., there is no adhesive force between the first support layer 201 and the adsorption jig, thereby improving the problem of the support pad 20 being detached from the main body portion 11 caused by the adhesion between the adsorption jig and the second sub-portion 22.

A material of the first support layer 201 may include polyethylene terephthalate (PET) and polyimide (PI), and a material of the first adhesive layer 203 may include pressure sensitive adhesive (PSA).

The specific structure of the support portion 202 will be illustrated by examples below.

In some examples, as shown in FIG. 7, the support portion 202 includes a second adhesive layer 2021. A material of the second adhesive layer 2021 may include pressure sensitive adhesive. The first support layer 201 and the bonding portion 13 are stuck by the second adhesive layer 2021.

In some other examples, as shown in FIG. 8, the support portion 202 includes a second adhesive layer 2021, a second support layer 2022 and a third adhesive layer 2023.

The second support layer 2022 is located on a side of the second adhesive layer 2021 away from the bonding portion 13, and is overlapped with and flush with the second adhesive layer 2021. The second support layer 2022 is used to provide support to enhance rigidity of the support pad 20, so that the support pad 20 may well support the bonding portion 13. The second support layer 2022 may have a single-layer structure or a multiple-layer structure, which is not specifically limited in the embodiments of the present disclosure.

It will be noted that a material of the second support layer 2022 may include polyethylene terephthalate and polyimide.

The third adhesive layer 2023 is located on a side of the second support layer 2022 away from the bonding portion 13, and is overlapped with and flush with the second support layer 2022. A material of the third adhesive layer 2023 may include pressure sensitive adhesive. The third adhesive layer 2023 may be made of the same material as the second adhesive layer 2021. For example, the third adhesive layer 2023 and the second adhesive layer 2021 may both be made of pressure sensitive adhesive.

In some examples, as shown in FIGS. 7 and 8, a surface of the support portion 202 proximate to the bonding portion 13 is flush with a surface of the first support layer 201 proximate to the bonding portion 13.

Such a provision may allow the surface of the first support layer 201 proximate to the bonding portion 13 to be in direct contact with the bonding portion 13, so as to improve a problem of a second adhesive overflow channel formed by a gap between the surface of the first support layer 201 proximate to the bonding portion 13 and the bonding portion 13, thereby preventing the injected adhesive from flowing through the second overflow adhesive channel to other parts (e.g., the display area A) of the display module 100. As a result, the display effect of the display module 100 may be improved.

In some examples, as shown in FIGS. 7 and 8, there is a gap between a boundary of an orthographic projection of the support portion 202 on the main body portion 11 and an outer boundary of an orthographic projection of the receiving groove 2011 on the main body portion 11. With such a provision, the support portion 202 may be located in the receiving groove 2011.

For example, as shown in FIGS. 7 and 8, a distance between the boundary of the orthographic projection of the support portion 202 on the main body portion 11 and the outer boundary of the orthographic projection of the receiving groove 2011 on the main body portion 11 is in a range of 0.3 mm to 0.5 mm, inclusive.

For example, the distance between the boundary of the orthographic projection of the support portion 202 on the main body portion 11 and the outer boundary of the orthographic projection of the receiving groove 2011 on the main body portion 11 is 0.3 mm, 0.32 mm, 0.35 mm, 0.36 mm, 0.39 mm, 0.40 mm, 0.44 mm, 0.47 mm or 0.5 mm, and the embodiments of the present disclosure do not list one by one.

In some embodiments, as shown in FIGS. 7 and 8, in the first direction X, a distance between a boundary of an orthographic projection of the bonding portion 13 on the main body portion 11 and an outer boundary of an orthographic projection of the receiving groove 2011 on the main body portion 11 is in a range of 1.7 mm to 2.9 mm, inclusive.

For example, the distance between the boundary of the orthographic projection of the bonding portion 13 on the main body portion 11 and the outer boundary of the orthographic projection of the receiving groove 2011 on the main body portion 11 is 1.7 mm, 1.71 mm, 1.75 mm, 1.79 mm, 1.8 mm, 1.83 mm, 1.86 mm, 1.9 mm, 2 mm, 2.3 mm, 2.4 mm, 2.6 mm, 2.8 mm or 2.9 mm, and the embodiments of the present disclosure do not list one by one.

Such a provision may allow the receiving groove 2011 to be relatively large, so that the support portion 202 may be made relatively large, and thus a contact area between the support portion 202 and the bonding portion 13 may be relatively large, thereby increasing the connection firmness between the support portion 202 and the bonding portion 13.

For example, as shown in FIGS. 7 and 8, in the first direction X, a distance between an outer boundary of an orthographic projection of the support portion 202 on the main body portion 11 and an outer boundary of an orthographic projection of the receiving groove 2011 on the main body portion 11 is in a range of 2 mm to 3 mm, inclusive.

For example, the distance between the outer boundary of the orthographic projection of the support portion 202 on the main body portion 11 and the outer boundary of the orthographic projection of the receiving groove 2011 on the main body portion 11 is 2 mm, 2.1 mm, 2.2 mm, 2.4 mm, 2.5 mm, 2.7 mm, 2.9 mm or 3 mm, and the embodiments of the present disclosure do not list one by one.

As shown in FIGS. 7 and 8, in the first direction X, a distance between an outer boundary of an orthographic projection of the first support layer 201 on the main body portion 11 and a boundary of an orthographic projection of the bonding portion 13 on the main body portion 11 is in a range of 150 μm to 250 μm, inclusive.

For example, the distance between the outer boundary of the orthographic projection of the first support layer 201 on the main body portion 11 and the boundary of the orthographic projection of the bonding portion 13 on the main body portion 11 is 150 μm, 160 μm, 180 μm, 190 μm, 200 μm, 205 μm, 213 μm, 220 μm, 225 μm, 233 μm, 240 μm, 245 μm or 250 μm, and the embodiments of the present disclosure do not list one by one.

In some other embodiments, as shown in FIG. 9, the support pad 20 includes a first support layer 201, a fourth adhesive layer 204 and a first adhesive layer 203. In the first direction X, two ends of the first support layer 201 extend beyond two ends of the bonding portion 13. The fourth adhesive layer 204 is located on a side of the first support layer 201 proximate to the bonding portion 13, and is overlapped with and flush with the first support layer 201. The first adhesive layer 203 is located on a side of the first support layer 201 away from the bonding portion 13, and is overlapped with and flush with the first support layer 201.

That is to say, in the first direction X, a portion of the first support layer 201 not extending beyond the bonding portion 13, a portion of the fourth adhesive layer 204 not extending beyond the bonding portion 13, and a portion of the first adhesive layer 203 not extending beyond the bonding portion 13 form the first sub-portion 21; and a portion of the first support layer 201 extending beyond the bonding portion 13, a portion of the fourth adhesive layer 204 extending beyond the bonding portion 13 and a portion of the first adhesive layer 203 extending beyond the bonding portion 13 form the second sub-portion 22. In addition, in the first direction X, the second sub-portion 22 is located on both sides of the first sub-portion 21.

With such a provision, the second sub-portion 22 is located on both sides of the first sub-portion 21, so that the first overflow adhesive channel in the related arts may be prevented from being formed, thereby improving the problem of affecting the normal display of the display module 100 caused by the injected adhesive flowing to other parts of the display module 100. In addition, during bending, the portion of the fourth adhesive layer 204 extending beyond the bonding portion 13 is in direct contact with the adsorption jig, and the portion of the fourth adhesive layer 204 extending beyond the bonding portion 13 has no stickiness, that is, there is no adhesive force between the fourth adhesive layer 204 and the adsorption jig, thereby improving the problem of the support pad 20 being detached from the main body portion 11 caused by the adhesion between the adsorption jig and the second sub-portion 22.

A material of the fourth adhesive layer 204 will be illustrated by examples below.

In some examples, the material of the fourth adhesive layer 204 is a light-curable adhesive layer. A portion of the fourth adhesive layer 204 overlapped with the bonding portion 13 is not exposed to ultraviolet light, and the portion of the fourth adhesive layer 204 overlapped with the bonding portion 13 has stickiness, so that the first support layer 201 and the bonding portion 13 may be stuck by the portion of the fourth adhesive layer 204 overlapped with the bonding portion 13. A portion of the fourth adhesive layer 204 extending beyond the bonding portion 13 is exposed to ultraviolet light, and the portion of the fourth adhesive layer 204 extending beyond the bonding portion 13 has no stickiness, so that there is no adhesive force between the fourth adhesive layer 204 and the adsorption jig, thereby improving the problem of the support pad 20 being detached from the main body portion 11 caused by the adhesion between the adsorption jig and the second sub-portion 22.

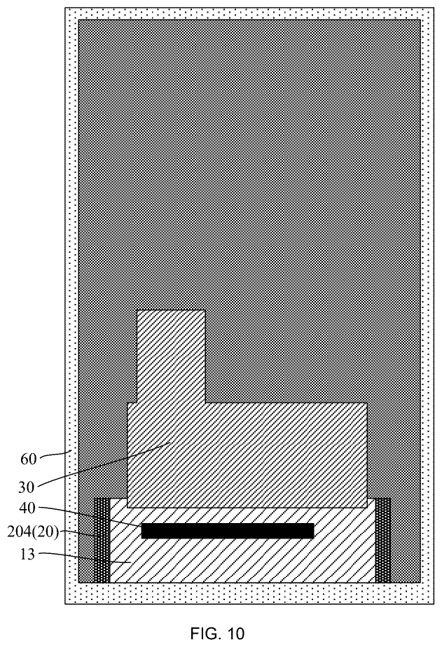

For example, as shown in FIGS. 9 and 10, between bending the bonding portion 13 and sticking the main body portion 11 to the bonding portion 13, the process of the bending process further includes: irradiating the fourth adhesive layer 204 vertically using ultraviolet light from a side of the bonding portion 13 away from the main body portion 11. Ultraviolet light cannot pass through the bonding portion 13, and thus the portion of the fourth adhesive layer 204 overlapped with the bonding portion 13 cannot be exposed to ultraviolet light and has stickiness. Moreover, there is no shielding on a side of the portion of the fourth adhesive layer 204 extending beyond the bonding portion 13 proximate to the bonding portion 13, and thus the portion of the fourth adhesive layer 204 extending beyond the bonding portion 13 is irradiated by ultraviolet light and has no stickiness.

In some examples, as shown in FIG. 9, in the first direction X, a distance between an outer boundary of an orthographic projection of the first support layer 201 on the main body portion 11 and a boundary of an orthographic projection of the bonding portion 13 on the main body portion 11 is in a range of 150 μm to 250 μm, inclusive.

For example, the distance between the outer boundary of the orthographic projection of the first support layer 201 on the main body portion 11 and the boundary of the orthographic projection of the bonding portion 13 on the main body portion 11 is 150 μm, 160 μm, 180 μm, 190 μm, 200 μm, 205 μm, 213 μm, 220 μm, 225 μm, 233 μm, 240 μm, 245 μm or 250 μm, and the embodiments of the present disclosure do not list one by one.

In some embodiments, as shown in FIGS. 2 and 3, the display module 100 further includes a driver chip 40, and the driver chip 40 is configured to provide the display panel 10 with data signals required for displaying images.

As shown in FIGS. 2 and 3, the driver chip 40 may be disposed on the bonding portion 13. In this way, the driver chip 40 may provide the data signals required for displaying images to the main body portion 11 through the bonding portion 13 and the bending portion 12, so as to control the display panel 10 to display images.

In addition, the driver chip 40 includes at least one of a source driver chip, a touch chip, a timing controller, a gamma circuit and other microchips, which is not specifically limited in the embodiments of the present disclosure.

In some embodiments, as shown in FIGS. 2 and 3, the display module 100 further includes a back film 50, and the back film 50 is located on the non-display side 11B of the display panel 10.

In some examples, as shown in FIGS. 2 and 3, the back film 50 may include a first back sub-film 501 and a second back sub-film 502, and the first back sub-film 501 and the second back sub-film 502 are disconnected at the bending portion 12.

Here, in a direction perpendicular to the main body portion 11, the first back sub-film 501 is at least partially overlapped with the main body portion 11. The second back sub-film 502 is at least partially overlapped with the bonding portion 13, and the second back sub-film 502 may be bent along the bonding portion 13 to the non-display side 11B of the main body portion 11 of the display panel 10.

In this case, the back film 50 exposes the bending portion 12 of the display panel 10, so that a bending resistance of the bending portion 12 of the display panel 10 may be reduced, and a position of a stress neutral layer in the bending portion 12 of the display panel 10 during bending may be changed, thereby avoiding damage to the display panel 10.

In some examples, as shown in FIGS. 2 and 3, an orthographic projection of a boundary of the main body portion 11 on the reference plane is located within an orthographic projection of a boundary of the first back sub-film 501 on the reference plane, that is, the first back sub-film 501 covers the main body portion 11, and an end of the first back sub-film 501 proximate to the second back sub-film 502 extends to the bending portion 12. An orthographic projection of a boundary of the bonding portion 13 on the reference plane is located within an orthographic projection of a boundary of the second back sub-film 502 on the reference plane, that is, the second back sub-film 502 covers the bonding portion 13, and an end of the second back sub-film 502 proximate to the first back sub-film 501 extends to the bending portion 12. The reference plane is parallel to a plane where the main body portion 11 is located.

In this case, during bending the display panel 10, stress concentration at the junctions of the main body portion 11, the bending portion 12 and the bonding portion 13 may be avoided, thereby reducing a risk of cracks or breakage of the display panel 10 at the junctions of the main body portion 11, the bending portion 12 and the bonding portion 13.

In some embodiments, as shown in FIG. 5, the display module 100 further includes a cover plate 60, a fifth adhesive layer 70, a circular polarizer 80 and a buffer layer 90.

As shown in FIG. 5, the cover plate 60 is located on a side of the main body portion 11 away from the bonding portion 13. With such a provision, the cover plate 60 may reduce the risk of the main body portion 11 being scratched.

The fifth adhesive layer 70 is located between the cover plate 60 and the main body portion 11. A material of the fifth adhesive layer 70 may include an adhesive material with high light transmittance (e.g., with light transmittance greater than or equal to 85%), such as optically clear adhesive (OCA) or pressure sensitive adhesive (PSA). For example, the material of the fifth adhesive layer 70 includes optically clear adhesive.

The circular polarizer 80 is located between the fifth adhesive layer 70 and the main body portion 11, and at least covers the display area A. The circular polarizer 80 may reduce reflection of ambient light by the main body portion 11.

The buffer layer 90 is located between the main body portion 11 and the support pad 20 and covers at least the display area A. The buffer layer 90 mainly plays a role of buffering and anti-vibration, so as to improve an impact resistance of the display module 100. A material of the buffer layer 90 includes a super clean foam (SCF) composite film.

In the description of the specification, the specific features, structures, materials or characteristics may be combined in any one or more embodiments or examples in a suitable manner.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A display module, comprising:
a display panel including a main body portion, a bonding portion, and a bending portion located between the main body portion and the bonding portion, wherein the main body portion has a display side and a non-display side that are disposed opposite to each other, and the bending portion is bent around a bending axis extending in a first direction towards the non-display side of the main body portion, so that the bonding portion is bent to the non-display side of the main body portion; and
a support pad located between the main body portion and the bonding portion, wherein the support pad includes a first sub-portion and a second sub-portion; in the first direction, the second sub-portion is located on at least one side of the first sub-portion, and two ends of the first sub-portion are flush with two ends of the bonding portion; wherein
the first sub-portion is configured to have no adhesive force with an adsorption jig when separated from the adsorption jig.

2. The display module according to claim 1, wherein the support pad includes:
a first support layer, wherein in the first direction, two ends of the first support layer extend beyond the two ends of the bonding portion, and a surface of the first support layer proximate to the bonding portion is provided with a receiving groove therein; an orthographic projection of the receiving groove on the main body portion is located within an orthographic projection of the bonding portion on the main body portion;
a support portion located in the receiving groove; the first support layer and the bonding portion being connected by the support portion; and
a first adhesive layer located on a side of the first support layer away from the bonding portion, and overlapped with and flush with the first support layer.

3. The display module according to claim 2, wherein the support portion includes:
a second adhesive layer;
a second support layer located on a side of the second adhesive layer away from the bonding portion; and
a third adhesive layer located on a side of the second support layer away from the bonding portion.

4. The display module according to claim 2, wherein a surface of the support portion proximate to the bonding portion is flush with a surface of the first support layer proximate to the bonding portion.

5. The display module according to claim 2, wherein a boundary of an orthographic projection of the support portion on the main body portion and an outer boundary of an orthographic projection of the receiving groove on the main body portion have a gap therebetween.

6. The display module according to claim 2, wherein in the first direction, a distance between a boundary of the orthographic projection of the bonding portion on the main body portion and an outer boundary of an orthographic projection of the receiving groove on the main body portion is in a range of 1.7 mm to 2.9 mm, inclusive.

7. The display module according to claim 1, wherein the support pad includes:
a first support layer, wherein in the first direction, two ends of the first support layer extend beyond the two ends of the bonding portion;
a fourth adhesive layer located on a side of the first support layer proximate to the bonding portion, and overlapped with and flush with the first support layer, a portion of the fourth adhesive layer extending beyond the bonding portion having no stickiness; and
a first adhesive layer located on a side of the first support layer away from the bonding portion, and overlapped with and flush with the first support layer.

8. The display module according to claim 7, wherein a material of the fourth adhesive layer is a light-curable adhesive layer.

9. The display module according to claim 7, wherein in the first direction, a distance between an outer boundary of an orthographic projection of the first support layer on the main body portion and a boundary of an orthographic projection of the bonding portion on the main body portion is in a range of 150 μm to 250 μm, inclusive.

10. A display device, comprising the display module according to claim 1.

11. (canceled)

12. The display module according to claim 2, wherein the support portion includes a second adhesive layer, and the first support layer and the bonding portion are stuck by the second adhesive layer.

13. The display module according to claim 3, wherein the second support layer has a single-layer structure or a multiple-layer structure.

14. The display module according to claim 3, wherein a material of the first adhesive layer includes pressure sensitive adhesive, and/or a material of the second adhesive layer includes pressure sensitive adhesive, and/or a material of the third adhesive layer includes pressure sensitive adhesive.

15. The display module according to claim 2, wherein in the first direction, a distance between an outer boundary of an orthographic projection of the first support layer on the main body portion and a boundary of an orthographic projection of the bonding portion on the main body portion is in a range of 150 μm to 250 μm, inclusive.

16. The display module according to claim 1, further comprising:
a back film located on the non-display side of the display panel, wherein
the back film includes a first back sub-film and a second back sub-film, and the first back sub-film and the second back sub-film are disconnected at the bending portion.

17. The display device according to claim 10, further comprising:
a middle frame including a bottom plate and a side frame disposed around the bottom plate, wherein the bottom plate is disposed on a side of the bonding portion of the display panel away from the main body portion, and the side frame is disposed around a circumference of the display panel.

18. The display device according to claim 11, wherein the fixing portion includes:
a first fixing portion covering a surface of the bending portion away from the side frame and extending to the main body portion and the bonding portion; and
a second fixing portion covering a surface of the bending portion proximate to the side frame and extending to the main body portion and the bonding portion.

19. The display device according to claim 17, further comprising: a fixing portion connecting the middle frame and the display module, wherein an orthographic projection of the fixing portion on a plane where the main body portion is located is located outside a display area of the display panel.
